(19) United States
(12) Patent Application Publication
(10) Pub. No.: US 2021/0098974 A1
(43) Pub. Date: Apr. 1, 2021

(54) CREATION OF AN ELECTRICAL CONNECTION BETWEEN COMPONENTS AND A CONTACTING PLATE

(71) Applicant: Siemens Aktiengesellschaft, Muenchen (DE)

(72) Inventors: Dirk POEHLER, Reinsdorf (DE); Klaus WILKE, Berlin (DE)

(73) Assignee: Siemens Aktiengesellschaft, Muenchen (DE)

(21) Appl. No.: 17/050,178

(22) PCT Filed: Apr. 12, 2019
(86) PCT No.: PCT/EP2019/059469

§ 371 Date: Oct. 23, 2020

(30) Foreign Application Priority Data
Apr. 25, 2018 (EP) 18169224.5

(51) Int. Cl. H02B 13/00; H05K 7/20

(52) U.S. Cl. CPC H02B 13/00; H05K 7/2039; H05K 7/20536

(57) ABSTRACT

A contacting plate is for creating an electrical connection to at least one component. The at least one component has a housing back, which is opposite the contacting plate. A method is for creating a contacting plate and the specification of options for electrical contacting between a component and contacting plate. An electrical contact and a mechanical fastening are formed between the contacting plate and the housing back of the at least one component.

### Priority Statement

This application is the national phase under 35 U.S.C. §371 of PCT International

Application No. PCT/EP2019/059469 which has an International filing date of Apr. 12, 2019, which designated the United States of America and which claims priority to European patent application EP18169224.5 filed Apr. 25, 2018, the contents of each of which are hereby incorporated by reference herein, in their entirety and for all purposes.

### FIELD

Embodiments of the invention generally relate to a contacting plate for the creation of an electrical connection to at least one component, wherein the at least one component has a housing back, which is opposite the contacting plate; the invention also relates to a method for producing a contacting plate and is also intended to specify possible ways of achieving the electrical contacting between the component and the contacting plate.

### BACKGROUND

A backplane is understood here as meaning a support for electrical components that has lines for electrically connecting electrical components. Such electrical components are for example low-voltage switching devices such as contactors, motor protecting switches, motor starters, soft starters or relays, or control units or input/output units. In a switching cabinet, electrical components of a technical apparatus or installation are arranged.

In conventional switching cabinets, electrical components are generally mechanically fastened on top-hat rails and electrically connected to one another and also to the outside by discrete insulated cables, which are laid in cable ducts. When there are many electrical components, this causes a great amount of cabling effort.

### SUMMARY

The inventors have discovered that there is a problem of accomplishing electrical contacting of components or switching devices in a switching cabinet as much as possible without cables. Apart from this electrical contacting of the components, the mechanical fastening must be performed; in some cases, a thermal connection must also be ensured for the removal of heat.

There are in principle a great many connection techniques from the area of frictionally engaging, interlocking or material-bonding joining technology, such as for example also spring contacts.

Embodiments of the present invention provide a contacting plate for the creation of an electrical connection, specify a method for producing this contacting plate and present possible ways of achieving the electrical contacting between the component and the contacting plate.

Embodiments of the invention are directed to a contacting plate, a method, a production process and also a contact element. Advantageous forms and developments, which can be used individually or in combination with one another, are the subject of the claims.

According to at least one embodiment of the invention, a contacting plate is for the creation of an electrical connection to at least one component, in particular in a switching cabinet, wherein the at least one component has a housing back, which is opposite the contacting plate. At least one embodiment of the invention is distinguished by the fact that electrical contacting and mechanical fastening are formed between the contacting plate and the housing back of the at least one component.

At least one embodiment of the present invention is also directed to a method for producing a contacting plate for an electrical connection to at least one component, wherein the contacting plate is at least partially produced in an additive manufacturing process.

At least one embodiment of the present invention is also directed to a process for the creation of an electrical connection between a contacting plate and at least one electrical component in such a way that the at least one electrical component is oriented with its housing back toward the contacting plate, that a contact element for electrical contacting and if appropriate also for mechanical fastening is arranged between the contacting plate and the housing back of the at least one electrical component, and electrical contacting between the electrical component and the contacting plate and if appropriate also mechanical fastening of the electrical component on the contacting plate is produced by joining together the at least one electrical component and the contacting plate.

At least one embodiment of the present invention is also directed to a contact element for electrical contacting between an electrical component and a contacting plate, wherein the contact elements are formed as contact pins and are fastened in the backplane.

### BRIEF DESCRIPTION OF THE DRAWINGS

Further advantages and embodiments of the invention are explained in more detail below on the basis of an example embodiment and on the basis of the drawing, in which:

FIG. 1 shows in a side view a component, for example a switching device, with a contact element attached to the rear side, before mounting in a contacting plate according to the invention.

FIG. 2 shows in a side view a component, for example a switching device, with a contact element attached to the rear side, after mounting in the contacting plate according to the invention.

FIG. 3 shows in a view from below a contacting plate according to the invention with conductor track structures.

### DETAILED DESCRIPTION OF THE EXAMPLE EMBODIMENTS

According to at least one embodiment of the invention, a contacting plate is for the creation of an electrical connection to at least one component, in particular in a switching cabinet, wherein the at least one component has a housing back, which is opposite the contacting plate. At least one embodiment of the invention is distinguished by the fact that electrical contacting and mechanical fastening are formed between the contacting plate and the housing back of the at least one component.

Therefore, instead of the mounting plate that has been used up until now on the rear side of the switching cabinet and has only a mechanically supporting function, contacting plates are used, known as backplanes, which have universal electrical conductors applied by additive manufacturing techniques, such as for example dispensing printing or jetting, and can be individually produced customer-specifically.

At least one embodiment of the invention includes one or more additional contact elements, which can assume at least the function of the electrical contacting, if appropriate also additionally the mechanical contacting. These may for example be contact pins or contact strips. The contact pins may for example be permanently fastened in a fixed manner in the contacting plate or backplane, alternatively also in the components to be processed, for example on the rear side of the electrical components. As seen from the mounting side, the additively manufactured metallizations on the contacting plate may be located on the rear side, the front side or alternatively also on both sides.

According to at least one embodiment of the invention, it may be provided that special contact elements in the form of contact pins are arranged on the rear sides of the electrical components. The contact pins may be configured in such a way that they have metallic spring elements spreading out behind the backplane, which make electrical contacting possible. In addition, the metallic spring elements may make mechanical fastening of the component possible.

The conductor track structures are configured on the rear side of the backplane and are taken up to the edge of holes. When the devices are inserted, the contact elements automatically lock behind the backplane and thereby produce electrical and mechanical contacting. The advantage of this embodiment is that the conductor tracks are positioned on the rear side of the contacting plate, and consequently are not accessible from the front. In this way, the conductor tracks are mechanically protected from damage during mounting. Moreover, the use of a painted steel sheet as the rear wall provides shock protection for the printed conductor tracks.

A further embodiment of the invention is that there are contact elements or contact pins with a flexible pressing-in zone on the housing back of the component or switching device. On the contacting plate or backplane it is necessary for there to be metallized holes that are electrically insulated from the base material and are connected to the additively manufactured conductor runs. In order to dispense with metallized holes, the additive conductor runs could be taken at least up to the holes on the front side of the contacting plate. Moreover, the flexible contact elements or contact pins, i.e. the contact elements or contact pins with a flexible pressing-in zone, may have an additional spring element, for example in the form of a slit ring or collar, which accomplishes the electrical contacting. If need be, additional mechanical fastening of the device housings, for example by means of attaching with screws, is possible. The advantage of this embodiment is that the switching devices or components can be mechanically detached and if appropriate mechanically connected again. It is also possible that a new component or switching device is fitted at the same mounting location.

A further embodiment of the invention is that the pin contact is not located on the housing back of the components, but is positioned in a mechanically fixed manner in the contacting plate or backplane. Here, too, an insulated metallized hole wall is necessary, or alternatively just a hole that mechanically holds the pin of the contact element if the pin has an additional contacting possibility by means of an additional spring element, for example in the form of a slit ring or collar, which contacts the additive conducting structure. The devices with internal clamping structures, for example spring or screw contacting arrangements, are placed onto the contact pins of the contact elements. Just as in the above example embodiment, the connection is reversible, can therefore be broken and re-contacted. The components do not have any outward contact structures.

A further embodiment of the invention is that, before the production of the additive conductor tracks, the contact pins or contact elements are pressed into holes of the contacting plate or backplane and have a lateral or peripheral structure, which is overprinted in the dispensing process, and in this way an electrical connection is already accomplished. The advantage of this embodiment is that the pin contacts in the contacting plate or backplane are already electrically connected to the conductor tracks during their additive manufacturing process.

A further embodiment of the invention is that contact strips are used if a plurality of contact elements are required. These contact strips may for example be inserted in a mechanically fixed manner into milled slots in the contacting plate or backplane, if appropriate also with mechanical locking on the rear side. The respectively lateral electrical contacting with respect to the conductor tracks on the upper side of the backplane could for example already take place in the dispensing process of the conductor tracks. The switching devices or components are then fitted onto the contact strips and if appropriate additionally mechanically fastened. Alternatively, the contact strips may have lateral spring elements, which contact the metallizations of the conductor tracks. The advantage here is that a higher connection density is accomplished, i.e. a greater number of electrical contacts per unit area. Moreover, there are only planar structures on the upper side of the backplane and no metallized holes.

A development of this concept according to at least one embodiment of the invention may be that a thermal connection for the removal of heat is formed between the contacting plate and the housing back of the at least one component.

In a particularly advantageous refinement of the invention, it may be provided that at least one component or a plurality of components in a switching cabinet is/are electrically connected to the contacting plate.

It is also advantageous if the contacting plate is at least partially produced in an additive manufacturing process.

In a further special development of the concept according to at least one embodiment of the invention, it may be provided that the additive manufacturing process is a dispensing printing or a jetting of conductor tracks.

A development of this concept according to at least one embodiment of the invention may be that the contacting plate has contact elements on the front side and/or on the rear side.

In a particularly advantageous refinement of at least one embodiment of the invention, it may be provided that the housing back of the at least one component has contact elements.

It is also advantageous if the contact elements have metallic spring elements spreading out behind the backplane, i.e. the contacting plate, wherein the contact elements form electrical and mechanical contacting on the rear side of the contacting plate when the at least one component is inserted.

In a further special development of the concept according to at least one embodiment of the invention, it may be provided that contact elements with a flexible pressing-in zone are formed on the housing back of the at least one component.

A development of this concept according to at least one embodiment of the invention may be that the contact elements with a flexible pressing-in zone have an additional spring element, for example in the form of a slit ring or collar.

In a particularly advantageous refinement of at least one embodiment of the invention, it may be provided that the contacting plate has at least one contact element.

It is also advantageous if the contact elements are arranged on a contact strip.

At least one embodiment of the present invention is also directed to a method for producing a contacting plate for an electrical connection to at least one component, wherein the contacting plate is at least partially produced in an additive manufacturing process.

It may be advantageous if the additive manufacturing process is carried out as dispensing printing and/or jetting of conductor tracks.

At least one embodiment of the present invention is also directed to a process for the creation of an electrical connection between a contacting plate and at least one electrical component in such a way that the at least one electrical component is oriented with its housing back toward the contacting plate, that a contact element for electrical contacting and if appropriate also for mechanical fastening is arranged between the contacting plate and the housing back of the at least one electrical component, and electrical contacting between the electrical component and the contacting plate and if appropriate also mechanical fastening of the electrical component on the contacting plate is produced by joining together the at least one electrical component and the contacting plate.

At least one embodiment of the present invention is also directed to a contact element for electrical contacting between an electrical component and a contacting plate, wherein the contact elements are formed as contact pins and are fastened in the backplane.

It is in this case advantageous if a plurality of contact pins are formed in a contact strip

A development of this concept according to at least one embodiment of the invention may be that, apart from the electrical contacting, the contact elements are also formed as mechanical contacting.

The contacting plate, according to at least one embodiment of the invention is preferably configured rectangularly, with four different or equal side lengths, and serves as a mounting plate with a possibility for mechanical and electrical connection to the respective components or switching devices, so that the wiring effort can be minimized. The contacting plate is formed for example as a painted, sheet-like material with an insulating character and a conductor track structure. For the connection of the contact elements that are arranged on the housing back of a component or switching device, holes are provided in the contacting plate, so that a contact element can be led through the hole by metallic spring elements spreading out behind the backplane and can be anchored by the spreading out of the metallic spring elements. In the case of this embodiment, it is provided that the conductor tracks are arranged on the side of the contacting plate that is facing away from the component or switching device.

In a further embodiment, it is provided that the contact elements are positioned on the contacting plate on the side facing the component and electrical contacting is made possible by corresponding accesses in the component. In the event that additional mechanical fastening of the combination of the contacting plate and the component is required, a screw connection is for example possible.

The component may for example be a low-voltage switching device with a cuboidal construction comprising a front side, which serves as a connection side, and a mounting side, which is facing the contacting plate and serves as a housing back. The front side and the housing back are connected to one another by way of four side faces.

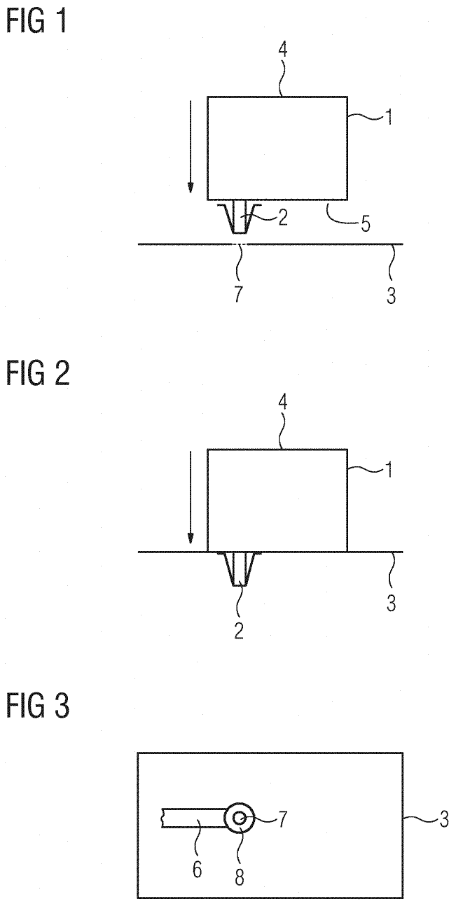

FIG. 1 shows a component 1, for example a switching device, with a contact element 2 attached to the rear side, preferably with a movable contact spring, before mounting in the contacting plate 3. The component 1 may be electrically and mechanically connected to the contacting plate 3 by way of the contact elements 2. The component 1 may be for example a low-voltage switching device with a cuboidal construction comprising a front side 4, which serves as a connection side, and a mounting side, which is facing the contacting plate 3 and serves as a housing back 5. The front side 4 and the housing back 5 are connected to one another by way of four side faces. The contact elements 2 are arranged on the housing back 5 of the component or switching device.

The contacting plate 3 according to the invention is preferably configured rectangularly, with four different or equal side lengths, and serves as a mounting plate with a possibility for mechanical and electrical connection to the respective components 1, so that the wiring effort can be minimized. The contacting plate 3 is preferably formed as a painted metal sheet with a conductor track structure. For the connection of the contact elements 2 that are arranged on the housing back 5 of the component 1, holes 7 are provided in the contacting plate 3, so that a contact element 2 having metallic spring elements spreading out behind the backplane can be led through and anchored. In the case of this embodiment, it is provided that the conductor track structures are arranged on the side of the contacting plate 3 that is facing away from the component 1.

FIG. 2 shows the component 1, for example a switching device, with a contact element 2 attached to the rear side, after mounting in the contacting plate 3. The component 1 may be electrically and mechanically connected to the contacting plate 3 by way of the contact elements 2. In the event that additional mechanical fastening of the combination of the contacting plate 3 and the component 1 is required, a screw connection is for example possible.

In FIG. 3, the view from below of the contacting plate 3 with conductor track structures 6 is shown. The contacting plate has a hole 7, which makes contact with the component 1 possible. Shown around the hole 7 is a printed contact area 8, extending from which a conductor track structure 6 is formed.

The contacting plate according to the invention is distinguished by the fact that, apart from a mechanical fastening function as a mounting plate, it enables an electrical contacting possibility for components or switching devices, in particular in a switching cabinet and consequently minimizes the wiring effort. The additive manufacturing process for the production of the conductor track structures, which can be adapted to individual needs and is for example in the form of dispensing printing, is a further advantage of the present invention.

### LIST OF DESIGNATIONS

1 Component

2 Contact element

3 Contacting plate

4 Front side

5 Housing back

6 Conductor track structure

7 Hole

8 Contact area

1. A contacting plate for the creation of an electrical connection to at least one component, the at least one component including a housing back, opposite the contacting plate, electrical contacting and mechanical fastening formed between the contacting plate and the housing back the at least one component.

2. The contacting plate of claim 1, wherein a thermal connection for removal of heat is formed between the contacting plate and the housing back of the at least one component.

3. The contacting plate of claim 1 wherein the at least one component, or a plurality of components in a switching cabinet, is electrically connected via the contacting plate.

4. The contacting plate of claim 1, wherein the contacting plate is at least partially produced in an additive manufacturing process.

5. The contacting plate of claim 4, wherein the additive manufacturing process is a dispensing printing or a jetting of conductor tracks.

6. The contacting plate of claim 1, wherein the contacting plate includes contact elements on at least one of a front side and a rear side.

7. The contacting plate of claim 1, where the housing back of the at least one component includes contact elements.

8. The contacting plate of claim 7, wherein the contact elements include metallic spring elements spreading out behind the backplane, and wherein the contact elements form electrical and mechanical contacting on a rear side of the contacting plate when the at least one component is inserted.

9. The contacting plate of claim 7, wherein the contact elements with a flexible pressing-in zone are formed on the housing back of the at least one component.

10. The contacting of claim 7, wherein contact elements with a flexible pressing-in zone include an additional spring element in the form of a slit ring or collar.

11. The contacting plate of claim 1, wherein the contacting plate includes at least one contact element.

12. The contacting plate of claim 1, wherein the contact elements are arranged on a contact strip.

13. A method for producing a contacting plate an electrical connection to at least one switching device, the method comprising:
at least partially producing the contacting plate in an additive manufacturing process.

14. The method of claim 13, wherein the additive manufacturing process is carried out as at least one of
dispensing printing jetting of conductor tracks.

15. A method of creating an electrical connection between a contacting plate and at least one electrical component, comprising:
orienting the at least one electrical component with a housing back, of the at least one electrical component, toward the contacting plate;
arranging a contact element for electrical contacting between the contacting plate the housing back of the at least one electrical component, and
producing electrical contacting between the electrical component and the contacting plate by joining together the at least one electrical component and the contacting plate.

16. A contact element for electrical contacting between an electrical component and a contacting plate, the contact element being formed as a contact pins and is fastened in a backplane.

17. The contact element of claim 16, wherein a plurality of contact pins are formed in a contact strip.

18. The contact element of claim 16, wherein the contact elements are also formed as mechanical contacting.

19. The contacting plate of claim 2, wherein the at least one component, or a plurality of components in a switching cabinet, is electrically connected via the contacting plate.

20. The contacting plate of claim 2, wherein the contacting plate is at least partially produced in an additive manufacturing process.
